(19) United States
(12) Patent Application Publication
(10) Pub. No.: US 2005/0155787 A1
(43) Pub. Date: Jul. 21, 2005

(54) Transparent small memory card

(76) Inventors: Pierre Liu, Hsinchu Hsien (TW); Allen Peng, Hsinchu Hsien (TW); Birdy Peng, Hsinchu Hsien (TW)

Correspondence Address: Keith Kline;PRO-TECHTOR INTERNATIONAL SERVICES, 20775 Norada Court, Saratoga, CA, 95070-3018, US

(21) Appl. No.: 10/761,601

(22) Filed: Jan. 20, 2004

(51) Int. Cl. H05K 7/06

(52) U.S. Cl. 174/250; 174/255

(57) ABSTRACT

A small memory card of present invention includes a substrate and at least one memory chip package, the substrate is formed with a placed region, a first terminal and a second terminal, the first terminal is formed with a plurality of golden fingers, the second terminal is formed with a pull slot, the substrate is inserted into an electric device, so that the plurality of golden fingers may be electrically connected to the electric device, and one memory chip package, which is arranged on the lay place of the substrate, electrically connected to the plurality of golden fingers. Thus, when the users operate the small memory card grasping the pull slot of the second terminal of the substrate by fingers, so that the small memory card may easily take out.

### BACKGROUND OF THE INVENTION

1. Field of the Invention

The present invention relates to a small memory card, and more particular to a small memory card could be operated conveniently.

2. Description of the Related Art

Referring to FIG. 1 showing the up-side schematic illustrates of a prior memory card, which includes a substrate 10 and at least one memory chip package 12, the substrate 10 is formed with a lay place 14, a first terminal 16 and a second terminal 18 on the both side of the lay place 14, the first terminal 16 formed with a plurality of golden fingers 20 and a gap 22, the gap may represent the side of the golden fingers, the substrate 10 is inserting into an electric device, so that the golden fingers 20 may be electrically connected to the electric device, a memory chip package 12, which is arranged on the lay place 14 of the substrate 10, electrically connected to a plurality of golden fingers 20.

Grasping the second terminal 18 of the substrate 10 of the conventional memory card by thumb and forefinger, then inserting into or taking out the first terminal 16 of the substrate 10 is more inconvenient.

### SUMMARY OF THE INVENTION

The object of the present invention is to provide a small memory card may be operated conveniently.

To achieve the above-mentioned object, the present invention includes a substrate and at least one memory chip package, the substrate is formed with a lay place, a first terminal and second terminal on the both side of the lay place, the first terminal is formed with a plurality of golden fingers, the second terminal is formed with a pull slot, the substrate is used for inserting into an electric device, and the memory chip package, which is mounted on the lay place of the substrate, electrically connected to the plurality of golden fingers.

According to one aspect of the present invention, the users may grasp the pull slot of the second terminal of the substrate by fingers, so the small memory card may be operated conveniently.

### BRIEF DESCRIPTION OF THE DRAWINGS

FIG. 1 is an up-side view showing a conventional small memory card structure.

FIG. 2 is an up-side view showing a small memory card of the present invention.

FIG. 3 is a cross-sectional view showing a small memory card of the present invention.

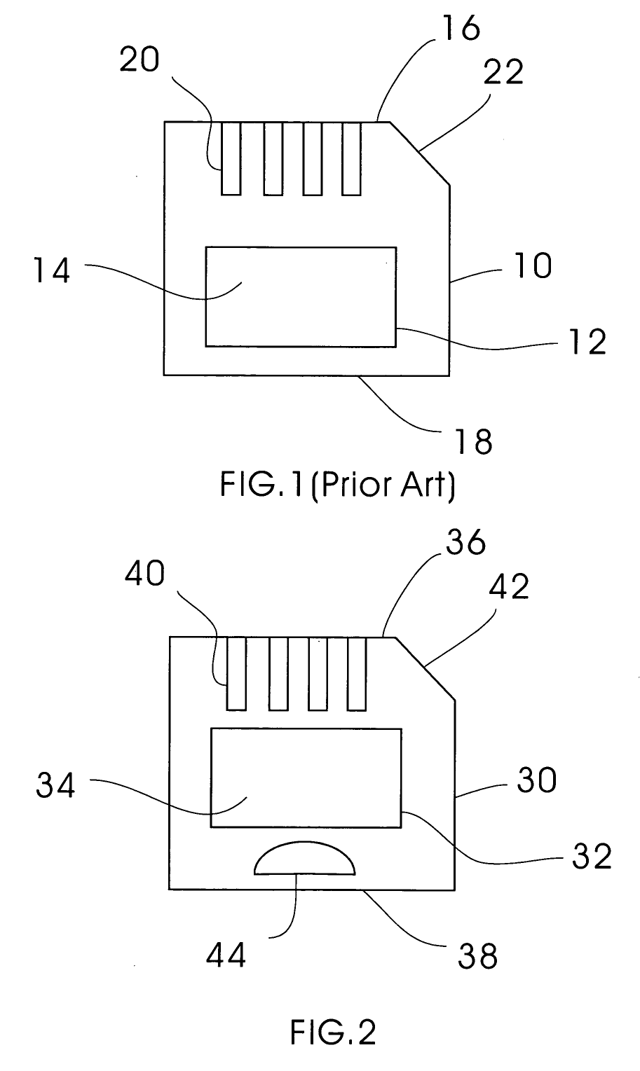

### DETAILED DESCRIPTION OF THE INVENTION

FIG. 2 is showing an up-side schematic illustrates showing a small memory card of the present invention, which included a substrate 30, and at least one memory chip package 32.

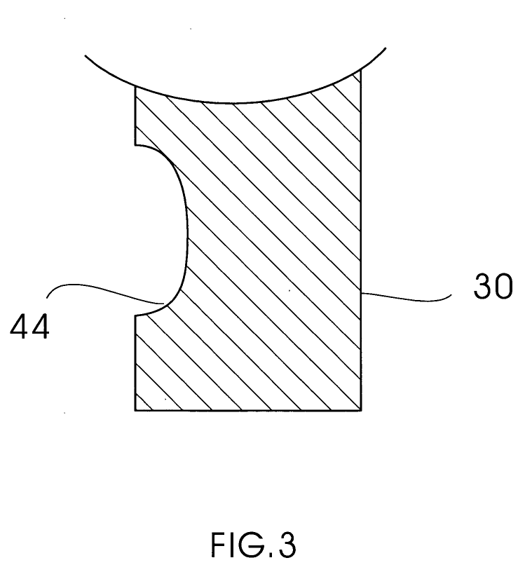

Referring to FIG. 3 is a cross-sectional view of the pull slot of the substrate of the present invention, the substrate 30 is formed with a first terminal 36 and second terminal 38 on both side of the placed region 34, the first terminal 36 is formed with a plurality of golden fingers 40 and a gap 42, the gap 42 is represent the side of the golden fingers 40, the second terminal 38 is formed with a pull slot 44 is arc-thumb shaped, the substrate 30 is used for inserting into an electric device, so that the plurality of golden fingers 40 may be electrically connected to the electric device.

The memory chip package 32, which is arranged on the lay place 34 of the substrate 30, electrically connected to a plurality of golden fingers 40.

Thus, users may grasp the pull slot 44 of the second terminal 38 of the substrate 30, so it is more conveniently when operating.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A small memory card to be set in an electric device, comprising:
A substrate having an placed region, a first terminal and a second terminal which placed on both side, the first terminal is formed with a plurality of golden fingers, the second terminal formed with a pull slot, the substrate being inserted into the electric device, so that the plurality of golden fingers may be electrically connected to the electric device; and
At least one memory chip package, which is arranged on the placed region of the substrate, electrically connected to a plurality of golden fingers.

2. The small memory card according to claim 1, wherein the first terminal of the substrate is formed with a gap.

3. The small memory card according to claim 1, wherein the pull slot of the second terminal of the substrate is arc shaped-shaped.

4. The small memory card according to claim 3, wherein the pull slot of the second terminal of the substrate shapes like a thumb-shaped.
